(19) United States
(12) Patent Application Publication
(10) Pub. No.: US 2010/0236089 A1
(43) Pub. Date: Sep. 23, 2010

(54) UV IRRADIATION APPARATUS AND UV IRRADIATION METHOD

(75) Inventors: Kimihiko Kawasaki, Tokyo (JP); Yota Aoki, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: LINTEC CORPORATION, Tokyo (JP)

(21) Appl. No.: 12/513,737

(22) PCT Filed: Oct. 29, 2007
(86) PCT No.: PCT/JP2007/071026

§ 371 Date: May 6, 2009

(30) Foreign Application Priority Data
Dec. 4, 2006 (JP) 2006-326720

(51) Int. Cl. F26B 3/34; H01L 33/48; G21K 5/02; G21K 5/10

(52) U.S. Cl. 34/275; 257/89; 250/492.2; 257/E33.056

(57) ABSTRACT

A UV irradiating portion 12 is provided with multiple UV light emitting diodes 21 arranged on a base plate 20 which is in a position corresponding to a semiconductor wafer attached with a protective sheet S through a UV curable adhesive layer 18 as an irradiation receiving body. The light emitting diodes 21 are arranged at intervals of substantially equal spaces along the direction substantially perpendicular to the relative movement direction with a wafer W. And, the light emitting diodes 21 in each row are arranged to have substantially the same peak wavelength, while the peak wavelengths of the light emitting diodes 21 in the adjacent rows are arranged to be not necessarily the same.

### TECHNICAL FIELD

The present invention relates to a UV irradiation apparatus and a UV irradiation method, and more particularly to a UV irradiation apparatus and a UV irradiation method using a light emitting diode.

### BACKGROUND ART

In a processing apparatus of a semiconductor wafer (hereinafter, simply referred to as “wafer”), processings such as sticking a protective tape onto a wafer for backgrinding, and sticking a dicing tape onto a wafer for individualing it into multiple chips are performed. For a tape to be used for the above processings, a UV curable type is adopted as its adhesive, so that peeling can be easily performed without breaking the wafer, by curing the adhesive to weaken its adhesion by a UV irradiation apparatus after the above processings.

As for the above-described UV irradiation apparatus, for example, an apparatus arranged with a lamp case in a position corresponding to a wafer surface, and arranged with a high-pressure mercury lamp, a metal halide lamp, or the like, inside the lamp case, is known (Patent Document 1).

And, as a luminous source for irradiation with UV rays, a UV irradiation apparatus using a light emitting diode is suggested from the applicant of this application (Patent Document 2).

Patent Document 1: Japanese Patent Application Laid-Open No. 9-162141

Patent Document 2: Japanese Patent Application Laid-Open No. 2006-40944

### DISCLOSURE OF THE INVENTION

### Problems to be Solved by the Invention

However, since the UV irradiation apparatus disclosed in Patent Document 1 is arranged to use the high-pressure mercury lamp as a luminous source, it has disadvantages that a high-voltage transformer is required, therefore equipment-size becomes larger, and electric power consumption becomes higher. Additionally, it requires frequent maintenance because of short life of the lamps, and it takes a long time until meeting the UV irradiation condition, so-called rise time, and therefore the lamp needs to be continuously turned ON during the operation time, that causes very high electric power consumption. Further, since irradiation control in accordance with the plane area of an irradiation receiving body cannot be performed, waste of electric power consumption is unavoidable. Moreover, since mercury is used for the lamp, an environmental problem regarding disposal thereof needs to be considered.

In these points, since Patent Document 2 has an arrangement in which the light emitting diode is adopted as its luminous source, downsizing of the apparatus as well as easiness of maintenance check, operability and power saving of UV irradiation can be remarkably achieved.

However, in the arrangement using the light emitting diode, a problem newly occurred that a UV curable-type adhesive could not be cured in some cases.

Many UV curable-type adhesives are designed that their initiators begin light curing at approximately 365 nm of wavelength. In contrast, initiators for UV curing have many types and some begin the reaction at other than 365 nm of wavelength. An emission spectrum of the high-pressure mercury lamp has, as shown in FIG. 6, the maximum peak at approximately 365 nm, and has multiple peaks at other region of wavelength. Therefore, in the case of the high-pressure mercury lamp, initiators which begin the reaction at other than 365 nm of wavelength could be used. However, the emission spectrum of a UV light emitting diode has, as shown in FIG. 7, only one peak at a specific wavelength. Consequently, when a wavelength for initiating reaction of the initiator differs from a light-emission wavelength of the UV light emitting diode, sometimes curing of the adhesive may become impossible.

### Object of the Invention

The present invention has been made in view of the above-described properties of a high-pressure mercury lamp and properties of a light emitting diode, in order to solve the problems in using the light emitting diode, based on knowledge and finding through various experiments; and an object is to provide a UV irradiation apparatus and a UV irradiation method while maintaining advantages in using the light emitting diode, while preventing occurrence of an uncured region in a UV curable-type adhesive.

### Means for Solving the Problems

In order to achieve the above objects, the present invention adopts such an arrangement that a UV irradiation apparatus arranged with a UV luminous body in a position corresponding to an irradiation receiving body, wherein

the UV luminous body comprises multiple types of UV light emitting diodes having different peak wavelengths.

According to the present invention, such an arrangement may be adopted that includes a base plate which is arranged substantially parallel to the irradiation receiving body, and is relatively movable with respect to the irradiation receiving body while maintaining the substantially parallel state; wherein

the light emitting diodes are supported by the base plate, and are arranged along the straight line substantially perpendicular to the relative movement direction at intervals of substantially equal spaces, and the rows are multiply provided along the relative movement direction; and

the peak wavelengths of the light emitting diodes in each row are set to be substantially the same, while the peak wavelengths in the adjacent rows are set to be not necessarily the same.

And, the light emitting diodes in the adjacent rows are preferably arranged to be positioned in between the adjacent light emitting diodes in each row viewing from the relative movement direction.

Also, such an arrangement maybe adopted that the light emitting diodes are provided to be attachable and detachable to and from the base plate.

Additionally, the light emitting diodes may be unitized respectively with two or more pieces in, and may be provided to be attachable and detachable to and from the base plate based on the respective units.

Further, such an arrangement may be adopted that the light emitting diodes are provided so that the luminous region can be controlled in accordance with plane area of the irradiation receiving body.

Furthermore, illuminance sensors may be arranged at intervals of equal spaces along the direction substantially perpendicular to the relative movement direction, on a table which supports the irradiation receiving body.

Still further, such an arrangement may be adopted that irradiating capacity of the light emitting diodes with respect to each unit being unitized with two or more pieces or with respect to each piece is detected by a current value and/or a voltage level.

The present invention adopts such an arrangement that a UV irradiation method in which multiple UV light emitting diodes are arranged in a position corresponding to an irradiation receiving body so as to irradiate with UV rays from the UV light emitting diodes onto the irradiation receiving body, wherein

multiple types of UV rays having different peak wavelengths are irradiated onto a UV irradiation region in the irradiation receiving body.

In the above method, the irradiation receiving body may be a sheet stuck to a semiconductor wafer through a UV curable adhesive.

### Advantageous Effect of the Invention

According to the present invention, since the UV irradiation apparatus includes multiple types of light emitting diodes having different peak wavelengths, even when UV curable-type adhesives different in properties of the initiators are used, UV rays having different wavelengths effect efficiently and UV curing over the whole region can be achieved. And, since the light emitting diodes are adopted as the luminous source, large-scaled equipment such as a transformer in the case of adopting a conventional lamp such as a mercury lamp becomes needless, whereby downsizing of equipment can be achieved. Additionally, when the light emitting diodes are arranged to be attachable and detachable to and from the base plate, maintenance by partial replacement can be easily achieved, and thereby allowing the burden of cost to be kept to a minimum. Further, when the UV luminous region is arranged to be controllable, product life of the light emitting diodes can be secured over a long period of time while electric power consumption can be lowered. Also, since a rise time like that of the high-pressure mercury lamp is not necessary, the light emitting diodes can be turned ON just before performing UV irradiation and can be turned OFF just after the end of the irradiation, therefore large amount of energy saving can be achieved compared to the high-pressure mercury lamp which is required to be continuously turned ON. Still further, when the illuminance sensors are provided, performance of the light emitting diodes can be assuredly evaluated, whereby insufficient UV irradiation can be avoided. Moreover, by controlling the current value and/or the voltage level using an ammeter and/or a voltmeter, a state of running out of a light emitting diode can be detected, whereby UV irradiation failure can be prevented.

### BRIEF DESCRIPTION OF THE DRAWINGS

FIG. 1 is a configuration diagram schematically showing a UV irradiation apparatus according to a preferred embodiment.

FIG. 2 is a plan view of an arrangement example of light emitting diodes showing in the direction of arrow A in FIG. 1.

FIG. 3 is a plan view schematically showing a state of controlling an initial luminous region of the light emitting diodes.

FIG. 4 is a plan view schematically showing a state of letting the whole region of the light emitting diodes to emit light.

FIG. 5 is a plan view schematically showing a state of controlling the light emitting diodes in accordance with the plane area of an irradiation receiving body.

FIG. 6 is an illustrative graphic showing an emission spectrum of a high-pressure mercury lamp.

FIG. 7 is an illustrative graphic showing an emission spectrum of a UV light emitting diode.

### EXPLANATION OF REFERENCE NUMERALS

10 UV IRRADIATION APPARATUS

11 WAFER SUPPORTING PORTION

12 UV IRRADIATING PORTION

17 ILLUMINANCE SENSOR

21 LIGHT EMITTING DIODE

W SEMICONDUCTOR WAFER (IRRADIATION RECEIVING BODY)

### BEST MODE FOR CARRYING OUT THE INVENTION

Hereinafter, a preferred embodiment of the present invention will be described with reference to the accompanying drawings.

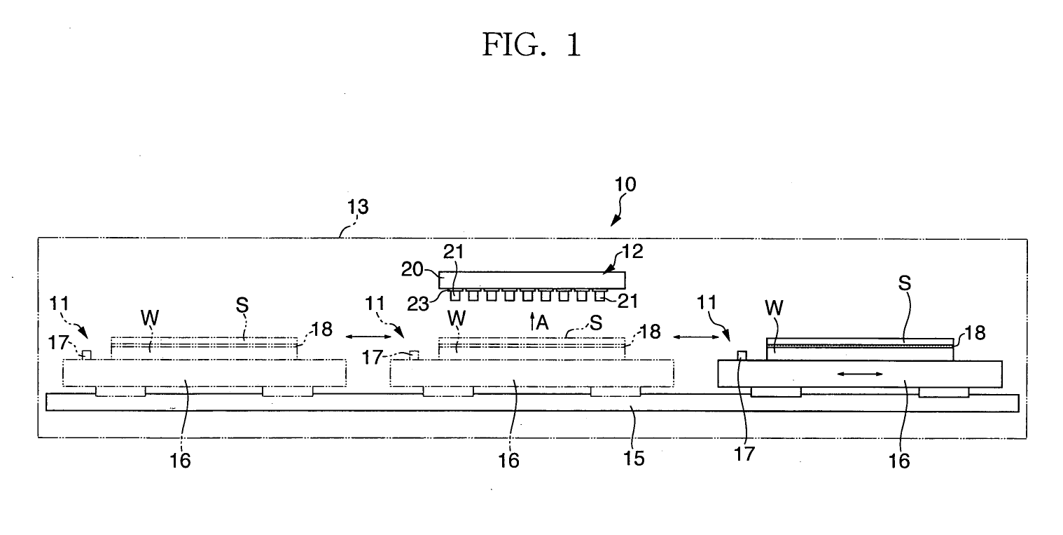

FIG. 1 shows a schematic front view according to a preferred embodiment of a wafer processing apparatus to which a UV irradiation apparatus according to the present invention is applied. In the figure, a UV irradiation apparatus 10 includes: a wafer supporting portion 11 for sucking and supporting a wafer W as an irradiation receiving body; a UV irradiating portion 12 which is arranged above the wafer supporting portion 11 to be substantially parallel to the wafer W; and a chamber 13 which surrounds these wafer supporting portion 11 and the UV irradiating portion 12.

The wafer supporting portion 11 includes a guide 15 which extends substantially parallel to the wafer W; a table 16 which is movably provided along the guide 15 and is formed of substantially a rectangular shape in plane view; and multiple illuminance sensors 17 which are arranged on the table 16 at intervals of equal spaces along the direction perpendicular to the front aspect of FIG. 1. The upper surface side of the table 16 is formed as an adsorption plane surface for sucking and fixing the wafer W. In this arrangement, the table 16 is formed relatively movable along the right-and-left direction in FIG. 1 (arrow direction) in the plane by a driving means (not shown in the figure) while maintaining substantially the parallel state with respect to the surface of the wafer W. Here, the irradiation receiving body includes the wafer W, and a protective sheet S which is stuck onto the upper surface side (a circuit surface side) of the wafer W through a UV curable-type adhesive layer 18. As for the protective sheet S, by curing the adhesive layer 18, the protective sheet S can be easily peeled off from the wafer W.

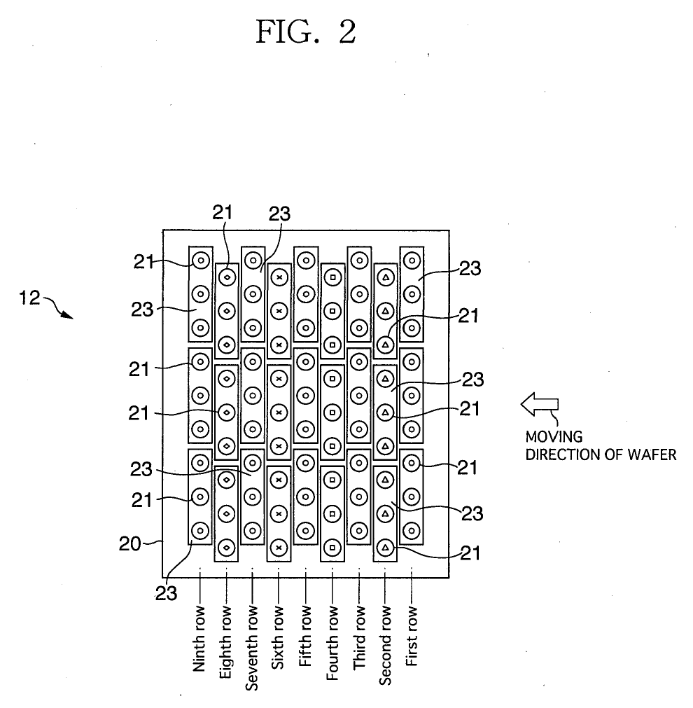

As shown in FIG. 2, the UV irradiating portion 12 is formed of substantially a rectangular shape in plane view, and is provided with a base plate 20 which is arranged substantially parallel to the wafer W, and a large number of UV light emitting diodes 21 which are arranged at intervals of equal spaces on the under surface side of the base plate 20 in FIG. 1. And, as shown in FIG. 2, the light emitting diodes 21 are arranged along the straight line (the vertical direction in the figure) substantially perpendicular to the relative movement direction, so that the light emitting diodes 21 in the adjacent rows are arranged to be positioned in between the adjacent light emitting diodes 21 in each row viewing from the relative movement direction. The light emitting diodes 21 are arranged in the first to ninth rows extending along the direction substantially perpendicular to the relative movement direction, in the illustrated example, in which each row includes nine light emitting diodes. And three light emitting diodes 21 in each row are supported by respective sockets 23, and the sockets 23 are provided to be attachable and detachable to and from the base plate 20. Optionally, the light emitting diodes 21 may be individually attachable and detachable to and from the respective sockets 23 or the base plate 20.

In the embodiment, the light emitting diodes 21 having substantially the same peak wavelength are adopted in the same row, so that the peak wavelengths are set to be different with respect to each row. To clarify the relationship, as shown in FIG. 2, mark of circle, triangle, square, x-mark, or rhombus is indicated in the light emitting diodes 21 illustrated by substantially a circular shape in plane view. As for the basic wavelength of irradiation, though it depends on the composition of the adhesive layer 18, for example, when a UV curable-type adhesive designed to be cured at UV rays of 365 nm wavelength is used, light emitting diodes 21 capable of irradiating with rays of 365 nm wavelength may be used for the 1st, 3rd, 5th, 7th, and 9th rows (indicated by circle marks in FIG. 2); and light emitting diodes 21 capable of irradiating with rays of other than 365 nm wavelength may be used for rows other than the 1st, 3rd, 5th, 7th, and 9th rows.

In the above arrangement, by relatively moving the wafer supporting portion 11 and the UV irradiating portion 12 in the state that the light emitting diodes 21 emit UV rays, the UV curable-type adhesive of the adhesive layer 18 can be cured. In this regard, even when an initiator having a different value from a design value is in the adhesive layer 18, the light emitting diodes 21 having different peak wavelengths effect so as to complement to each other, whereby a proportion of a cured region in the adhesive layer 18 can be increased.

The light emitting diodes 21 are evaluated by the illuminance sensors 17 each time the wafer W is irradiated with UV rays, therefore, whenever a lowered illuminance is detected, voltage with respect to each unit being unitized with one or more than one piece is raised, so that necessary illuminance can be secured. Also, even when the voltage reaches to the upper limit and an insufficient illuminance is detected, UV irradiation can be performed constantly in a steady performance by replacing with respect to each unit being unitized with one or more than one piece.

Thus, according to the embodiment as described above, a UV irradiation apparatus and a UV irradiation method having non-conventionally excellent functions and effects can be provided, in which possible occurrence of conventional disadvantages such as occurrence of an uncured region when using the UV light emitting diodes 21 can be prevented.

The best arrangement, method and the like for carrying out the present invention have been disclosed so far. However, the present invention is not limited to the above.

That is, the present invention has been illustrated and described mainly about a specific embodiment. However, it is possible for those skilled in the art to add various modifications, if necessary, to the above-described embodiment with respect to the shape, position and/or disposition without departing from the technical spirit and the range of the object of the present invention.

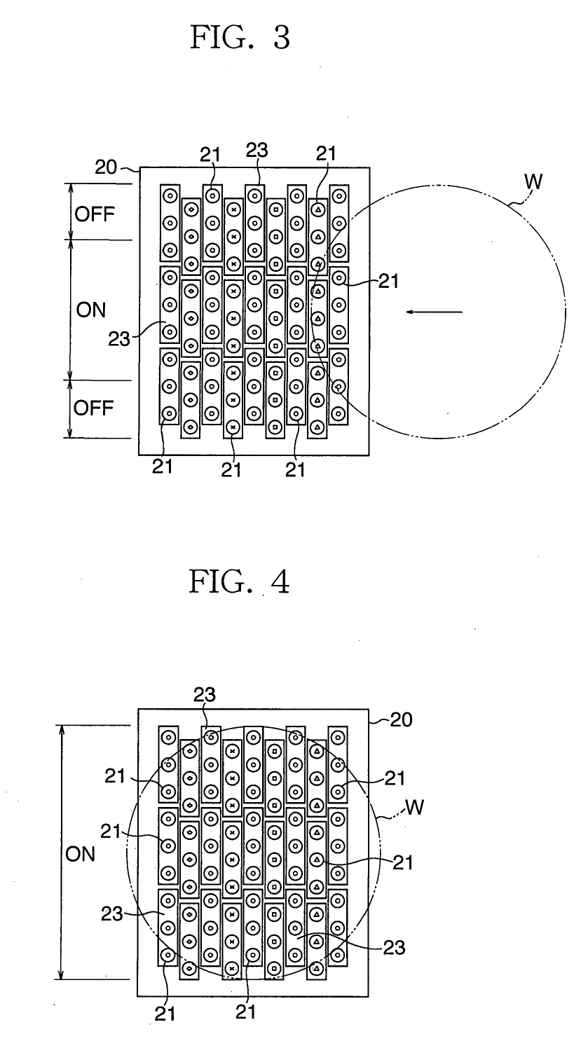

For example, as shown in FIG. 3, UV irradiation may be performed in another embodiment that light-emission timing of the light emitting diodes 21 is arranged to be individually controllable so as to emit in sequential order according to the timing of passage of the wafer W under the UV irradiating portion 12.

This control can be achieved by inputting address data of each light emitting diode 21 or each unit, and a speed of the above-described relative movement into a control device (not shown in the figure), in advance. In the example of FIG. 3, only the light emitting diodes within the region where the wafer W is positioned right under the light emitting diodes 21 are turned ON, and a light emitting diode 21 group or each unit group in both upper and lower sides in the figure are turned OFF, in this step. Accordingly, when the wafer W moves from the position in FIG. 3 to the position in FIG. 4, the light emitting diodes 21 in the whole region are turned ON, and as the wafer W further moves, the OFF region is to be wider gradually.

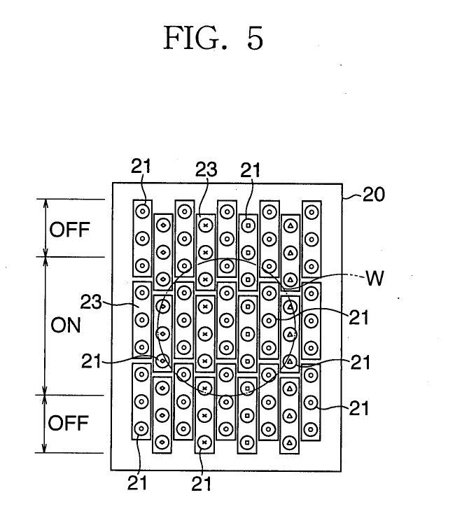

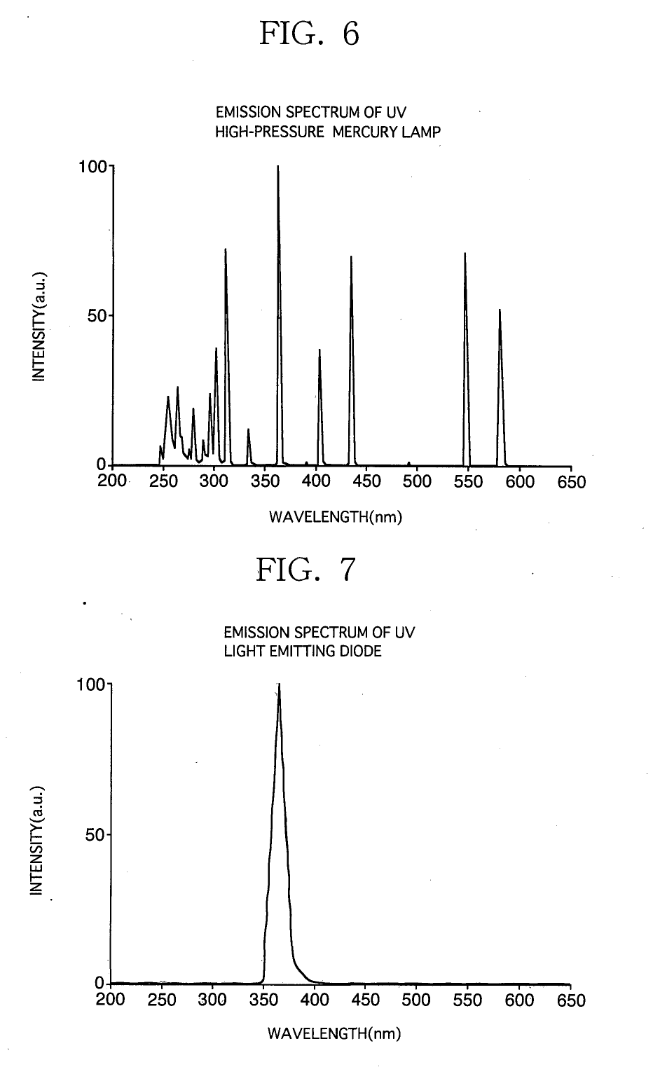

And, as shown in FIG. 5, when the size of the wafer W is smaller than the arranged region area of the light emitting diodes 21, the other region of the light emitting diodes 21 which cannot perform UV irradiation onto the wafer W may be maintained to be turned OFF constantly while performing UV irradiation.

Also, the current value and/or voltage level with respect to each unit being unitized with two or more pieces may be measured to detect whether the light emitting diodes 21 are emitting light. An arrangement of measuring the current value and/or voltage level with respect to each one piece may obviously be adopted.

Additionally, in the present invention, the irradiation receiving body is not limited to a semiconductor wafer, and there is no restriction to be applied to other materials as long as the subject needs a UV irradiation reaction without producing any unirradiated region.

Further, although the light emitting diodes 21 are arranged to have substantially the same peak wavelength with respect to each row in the embodiment, the light emitting diodes 21 having different peak wavelengths may be arranged in a random manner regardless of the rows. That means, it is enough for the present invention as long as multiple types of light emitting diodes are adopted, instead of using only one type of light emitting diodes having a specific peak wavelength. The numbers, rows, and arrangements are not limited to the illustrated arrangement examples.

Optionally, although the arrangement in which the relative movement is performed by moving of the table 16 which supports the wafer W with respect to the base plate 20 which supports the light emitting diodes 21 has been illustrated, it may be arranged by moving of the base plate 20 side through a suitable guide mechanism while the table 16 is fixed, or may be arranged by moving of both of the table 16 and the base plate 20.

Still further, at the time of UV irradiation, inside of the chamber 13 surrounding the wafer supporting portion 11 and the UV irradiating portion 12 may be filled with nitrogen gas or may be decompressed so as to prevent UV cure inhibition by oxygen.

1. A UV irradiation apparatus arranged with a UV luminous body in a position corresponding to an irradiation receiving body, wherein
the UV luminous body comprises multiple types of UV light emitting diodes having different peak wavelengths.

2. The UV irradiation apparatus according to claim 1, comprising a base plate which is arranged to be substantially parallel to the irradiation receiving body, and is provided to be relatively movable with respect to the irradiation receiving body while maintaining the substantially parallel state; wherein
the light emitting diodes are supported by the base plate, and are arranged at intervals of substantially equal spaces in a row along the straight line substantially perpendicular to the relative movement direction, and the row is multiply provided along the relative movement direction; and
the peak wavelengths of the light emitting diodes in each row are set to be substantially the same, while the peak wavelengths in the adjacent rows are set to be not necessarily the same.

3. The UV irradiation apparatus according to claim 2, wherein the light emitting diodes in the adjacent rows are arranged to be positioned in between the adjacent light emitting diodes in each row, viewing from the relative movement direction.

4. The UV irradiation apparatus according to claim 2, wherein the light emitting diodes are provided to be attachable and detachable to and from the base plate.

5. The UV irradiation apparatus according to claim 2, wherein the light emitting diodes are unitized respectively with two or more pieces into units, and are provided to be attachable and detachable to and from the base plate based on the unit.

6. The UV irradiation apparatus according to claim 1, wherein the light emitting diodes are provided so that the luminous region can be controlled in accordance with plane area of the irradiation receiving body.

7. The UV irradiation apparatus according to claim 1, wherein illuminance sensors are arranged at intervals of predetermined spaces along the direction substantially perpendicular to the relative movement direction, on a table which supports the irradiation receiving body.

8. The UV irradiation apparatus according to any claim 1, wherein irradiating capacity of the light emitting diodes with respect to each unit being unitized with two or more pieces or with respect to each piece is detected by a current value and/or a voltage level.

9. A UV irradiation method in which multiple UV light emitting diodes are arranged in a position corresponding to an irradiation receiving body so as to irradiate with UV from the UV light emitting diodes to the irradiation receiving body, wherein
multiple types of UV rays having different peak wavelengths are irradiated onto a UV irradiation region in the irradiation receiving body.

10. The UV irradiation method according to claim 9, wherein the irradiation receiving body is a sheet stuck to a semiconductor wafer through a UV curable adhesive.
